(19) United States
(12) Patent Application Publication
(10) Pub. No.: US 2024/0257845 A1
(43) Pub. Date: Aug. 1, 2024

(54) SYSTEM AND METHODS FOR COMMUNICATION OVER MULTIFUNCTION PINS

(71) Applicant: Microchip Technology Incorporated, Chandler, AZ (US)

(72) Inventors: Ali Harb, Gilbert, AZ (US); Daniel Meacham, Del Mar, CA (US); Anthony Andresen, Chandler, AZ (US); Mitch Polonsky, Chandler, AZ (US)

(73) Assignee: Microchip Technology Incorporated, Chandler, AZ (US)

(21) Appl. No.: 18/381,776

(22) Filed: Oct. 19, 2023

Related U.S. Application Data
(60) Provisional application No. 63/441,374, filed on Jan. 26, 2023.

(51) Int. Cl. G11C 7/10; G11C 7/22; H03K 19/017

(52) U.S. Cl. CPC G11C 7/1063; G11C 7/222; H03K 19/01742

(57) ABSTRACT

In an I2C communication system, dedicated address pins may enable a primary device to separately address multiple secondary devices. Upon a first transmission from the primary device, the logic level on each dedicated address pin may be saved in each secondary device. The address decoder circuit within each secondary device may use the saved address pin value for decoding transmissions from the primary device. The dedicated address pin may then be re-used for a separate function, as the logic level on the address pin has been saved.

### PRIORITY

This application claims priority to commonly owned U.S. Patent Application No. 63/441,374 filed Jan. 26, 2023, the entire contents of which are hereby incorporated by reference for all purposes.

### TECHNICAL FIELD

The present disclosure relates to pins on an integrated circuit, more specifically to a system and method for communicating over multifunction pins.

### BACKGROUND

Integrated circuit components may communicate over one of many communication protocols. In order to reduce the number of external pins required for communication, communication protocols have been developed which only require two pins, including but not limited to Inter-Integrated Circuit (I2C), System Management Bus (SMBus), and Serial Parallel Interface (SPI). The term “pins” as used herein is not meant to be limited to a particular structure, and is meant to include any connection, including without limitation, a pad, a wire or a ball.

The I2C communication protocol is one such protocol used for connecting multiple integrated circuit components in a single system. I2C is a 2-wire serial interface utilizing a serial clock line (SCL) and a serial data line (SDA). The I2C protocol relies on a specific pattern of signals on the SCL and SDA lines to indicate the beginning (START) and end (STOP) of a transmission.

An I2C system may include a primary device which may drive a specific pattern of voltages on the SCL and SDA lines, and at least one secondary device which may receive the SCL and SDA lines as an input and may control the voltage of the SDA line at predetermined times. The specific pattern of voltages on the SCL line may be termed a clock signal, and the specific pattern of voltages on the SDA line may be termed a data signal.

I2C is a shared-bus protocol, with all devices connected to the SCL and SDA lines. A pull-up resistor may be connected between the SCL line and a power supply. A pull-up resistor may be connected between the SDA line and a power supply. In order to allow for communication with fewer than all the devices connected to the SCL and SDA lines, individual devices are assigned a chip address value. A primary device may send a clock signal over the SCL line and a data signal over the SDA line, and when a secondary device decodes the received clock signal and data signal and the decoded chip address matches the chip address value, the remainder of the data transmission is acted upon only by secondary devices matching that chip address value and the data transmission is ignored by other secondary devices.

It may be desirable to have multiple instances of the same secondary device in a single I2C system. In one of various examples, a multi-channel audio system may include multiple audio amplifiers, one amplifier for each channel. For the purposes of this discussion, there may be 4 audio amplifiers in a multi-channel system. The 4 audio amplifiers may be referred to respectively as left-front, right-front, left-rear and right-rear. When the chip address value for the audio amplifiers is transmitted over the SCL and SDA lines, all 4 amplifiers will recognize the chip address value, and the remainder of the data transmission will be acted upon by all 4 amplifiers. As one of various examples, a request to lower the volume may be transmitted and acted upon by all 4 audio amplifiers with a single data transmission over the I2C bus.

In one of various examples, a user may desire to modify the volume at only one of the audio amplifiers. As one of various examples, in a vehicle implementation a driver may desire to modify the volume to focus the sound on the driver's location by setting the right-front, left-rear and right-rear amplifiers to full attenuation. The I2C protocol allows for at least one address pin to enable addressing individual instances of secondary devices.

In operation, the chip address value may be comprised of a common chip address value assigned to the most significant bits of the chip address value, and a variable chip address value assigned to at least one of the least significant bits of the chip address value, the variable chip address value set by dedicated address pins on the secondary device. In one of various examples using two dedicated address pins, the common chip address value may be shared by all of the identical secondary devices, and the two least significant bits of the chip address value may be set by the voltage on the dedicated address pins of respective secondary devices. A user may use resistive pull-ups and pull-downs to set the variable chip address value for each of the 4 devices. In other examples, a microcontroller or other host device may set the voltage on the dedicated address pins.

In the addressing scheme described above, the dedicated address pins are used solely for setting the address of the secondary device and are not used for other functions of the secondary device. In very small devices, dedicating two pins merely for an initial addressing function can limit the functionality of the device.

There is a need for an I2C addressing scheme which allows address pins to be reused for other functions.

### SUMMARY

The examples herein enable a system in which address pins may be used as multifunction pins.

According to one aspect, the examples herein enable a device including a clock input port, a bidirectional data port, and an address port. An address decoder circuit may be coupled to the clock input port, the bidirectional data port and the address port. The address decoder circuit may receive a clock signal from the clock input port and may receive a data signal from the bidirectional data port, and may decode the clock signal and the data signal to generate a decoded address field. The address decoder circuit may store the value of the address port in a non-transitory storage location and may compare at least one bit of the decoded address field to the stored value of the address port. An internal control circuit may output a control signal to a pull-down circuit based on a predetermined condition, the pull-down circuit may selectively couple the address port to a ground node based on the value of the control signal.

According to one aspect, the examples herein enable a system with a primary device to drive a clock bus and a data bus and to couple to a control bus. The system may include a plurality of secondary devices comprising a clock input port to couple to the clock bus, a bidirectional data port to couple to the data bus, and an address port to couple to the control bus. An address decoder circuit may be coupled to the clock input port, the bidirectional data port and the address port. The address decoder circuit may receive a clock signal from the clock input port and may receive a data signal from the bidirectional data port, and may decode the clock signal and the data signal to generate a decoded address field. The address decoder circuit may store the value of the address port in a non-transitory storage location and may compare at least one bit of the decoded address field to the stored value of the address port. An internal control circuit may output a control signal to a pull-down circuit based on a predetermined condition and the pull-down circuit may selectively couple the address port to a ground node based on the value of the control signal.

According to one aspect, the examples herein may enable a method including operations of: receiving a data transmission from a primary device at a secondary device, storing the value of an address port to a stored address location in a non-transitory storage device, decoding the data transmission to generate a decoded address field, comparing at least one bit of the decoded address field with the stored address port value, and pulling down the voltage of the address port, based on a predetermined condition of the secondary device, to signal a status condition to the primary device.

### BRIEF DESCRIPTION OF THE FIGURES

FIG. 1A illustrates one of various examples of an addressing scheme.

FIG. 1B illustrates another example of an addressing scheme.

FIG. 2 illustrates one of various examples of a I2C device including a multifunction address pin.

FIG. 3 illustrates one of various examples of a system of two I2C devices, each device including a multifunction address pin.

FIG. 4 illustrates another example of a system of two I2C devices, each device including a multifunction address pin.

FIG. 5 illustrates a method of configuring and using a multifunction address pin.

### DETAILED DESCRIPTION

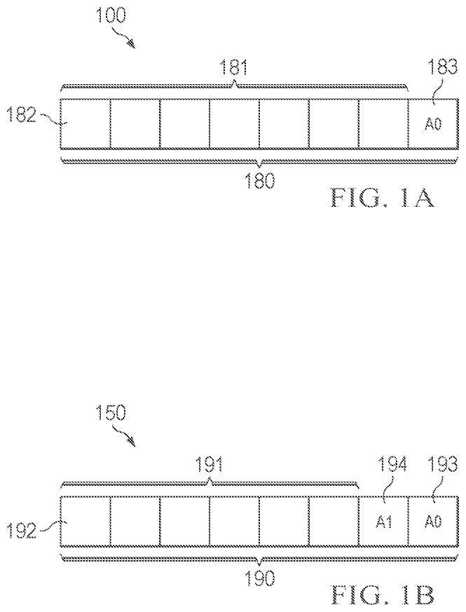

FIG. 1A illustrates one of various examples of an addressing scheme 100. Address field 180 may represent an address used in communication between a primary device and one or more secondary devices. Address field 180 may include a plurality of bits, from a most significant bit 182 to a least significant bit 183. A secondary device may include a chip address value. A secondary device may respond to communication from a primary device when the address field 180 transmitted from the primary device matches the chip address value of the secondary device. A secondary device may ignore communication when the address field 180 transmitted from the primary device does not match the chip address value of the secondary device.

In operation, the seven most significant bits 181 of address field 180 may represent a common address. The common address may be hard coded in the secondary device by a memory component, including but not limited to a register or a read-only memory. The least-significant bit 183 may represent a variable address. Least significant bit 183 may also be referred to as address bit A0. Address bit A0 may be set by an external pin value. Address bit A0 allows the primary device to selectively address two sets of secondary devices.

The example of FIG. 1A is illustrated with an 8-bit address field, but this is not intended to be limiting. The address field may include more than 8 bits, or less than 8 bits.

FIG. 1B illustrates one of various examples of an addressing scheme 150. Address field 190 may represent an address used in communication between a primary device and one or more secondary devices. Address field 190 may include a plurality of bits, from a most significant bit 192 to a least significant bit 193. A secondary device may include a chip address value. A secondary device may respond to communication from a primary device when the address field 190 transmitted from the primary device matches the chip address value of the secondary device. A secondary device may ignore communication when the address field 190 transmitted from the primary device does not match the chip address value of the secondary device.

In operation, the six most significant bits 191 of address field 190 may represent a common address. The common address may be hard coded in the secondary device by a memory component, including but not limited to a register or a read-only memory. The least-significant bit 193 may represent a first bit of a variable address. Least significant bit 193 may also be referred to as address bit A0. Address bit A0 may be set by an external pin value. The next-to-least-significant bit 194 may represent a second bit of the variable address. Next-to-least-significant bit 194 may also be referred to as address bit A1. Address bit A1 may be set by an external pin value. Address bit A0 and address bit A1 allow the primary device to selectively address up to four sets of secondary devices.

The example of FIG. 1B is illustrated with an 8-bit address field, but this is not intended to be limiting. The address field may include more than 8 bits, or less than 8 bits.

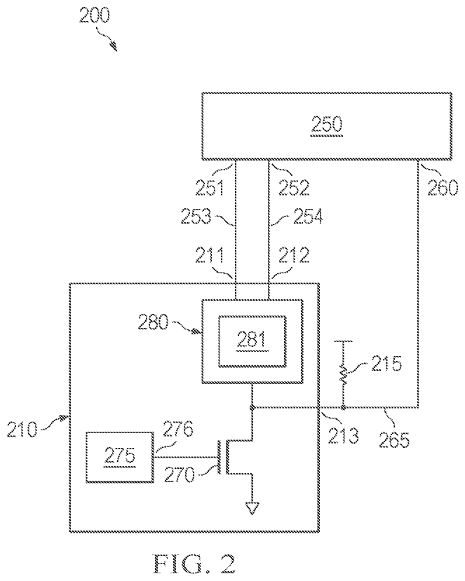

FIG. 2 illustrates one of various examples of a system 200 including a multifunction address pin. A primary device 250 may include an output clock port 251. Primary device 250 may include a bidirectional data port 252. Primary device 250 may be an I2C host device capable to communicate with one or more secondary devices using the I2C communication protocol. In the example illustrated in FIG. 2, primary device 250 may communicate with secondary device 210.

Primary device 250 may be a microcontroller. Microcontrollers are systems on a chip that generally comprise a processor, a memory, a plurality of input/output ports, and a variety of peripheral devices. In particular, a variety of peripheral devices can be provided such as configurable logic cells, complementary waveform/output generators, dedicated arithmetic units, numerical controlled oscillators and programmable switch mode controllers. Microcontrollers may include host controllers to communicate with peripheral devices over a communication protocol, the communication protocol including but not limited to I2C. Primary device 250 may comprise a digital processor with memory and a plurality of programmable input and output ports. Primary device 250 may be a host device capable to communicate with multiple secondary devices over a shared bus protocol.

Secondary device 210 may comprise a peripheral device as described previously, including but not limited to a sensor, amplifier, oscillator, battery gauge, data converter or a logic device. Secondary device 210 may communicate with primary device 250 using a communication protocol, the communication protocol including but not limited to I2C.

Output clock port 251 may be coupled to at least one secondary device via shared bus 253. Shared bus 253 may also be termed an SCL or shared SCL bus. Bidirectional data port 252 may be coupled to at least one secondary device via shared bus 254. Shared bus 254 may also be termed an SDA or shared SDA bus. In the example illustrated in FIG. 2, system 200 includes one secondary device 210, but this is not intended to be limiting. Other examples may include more than one secondary device. In examples including more than one secondary device, shared bus 253 may be shared among the more than one secondary devices, and shared bus 254 may be shared among the more than one secondary devices. Shared bus 253 and shared bus 254 may be coupled to pull-up or pull-down resistors as specified by the communication protocol.

Secondary device 210 may include clock input port 211. Clock input port 211 may be coupled to shared SCL bus 253. Secondary device 210 may include bidirectional data port 212. Bidirectional data port 212 may be coupled to shared SDA bus 254. Secondary device 210 may include first address port 213. First address port 213 may be coupled to a power supply voltage through pull-up resistor 215. The value of first address port 213 may be stored in non-transitory memory location 281, and the value stored in non-transitory memory location 281 may set the value of address bit A0 of the chip address value of secondary device 210. The remaining bits of the chip address value of secondary device may be stored in memory in secondary device 210 or otherwise hard-coded in secondary device 210.

In operation, primary device 250 may transmit a clock signal on shared SCL bus 253 and may transmit a data signal on shared SDA bus 254. Secondary device 210 may receive the transmitted data signal on bidirectional data port 212. Secondary device 210 may receive the transmitted clock signal on clock input port 211. Address decoder circuit 280 in secondary device 210 may receive inputs from clock input port 211, bidirectional data port 212 and non-transitory memory location 281 and decode an address field based upon the signals received at clock input port 211 and bidirectional data port 212 and the value stored in non-transitory memory location 281. Secondary device 210 may include a chip address value stored in memory in secondary device 210 or otherwise hard-coded in secondary device 210. Address decoder circuit 280 may compare the decoded address field and the chip address value.

Secondary device 210 may respond to transmissions with the decoded address field matching the chip address value. The chip address value may include a common address and a variable address. In the example illustrated in FIG. 2, the variable address of the chip address value may be set by the value stored in non-transitory memory location 281. In the example illustrated in FIG. 2, the variable chip address value may be the least significant bit of the chip address value, and the common chip address value may be the most significant bits of the chip address value.

At the first transmission from primary device 250, address decoder circuit 280 may sample the voltage at first address port 213. Address decoder circuit 280 may store the sampled value of first address port 213 in non-transitory storage location 281, including but not limited to a volatile register or latch that stores the value of first address port 213 for as long as the device is receiving a supply voltage. In the example illustrated in FIG. 2, address decoder circuit 280 may store the value of first address port 213, storing a logic-high value into the non-transitory storage location 281.

The value stored in non-transitory storage location 281 may be used by address decoder circuit 280 as the variable portion of the chip address value, address bit A0. Address decoder circuit 280 may compare the decoded address field to the chip address value for secondary device 210, with the least significant bit of the chip address value from the non-transitory storage location 281.

Once the value of first address port 213 is stored in non-transitory storage location 281, first address port 213 may be repurposed to a new function. In the example illustrated in FIG. 2, first address port 213 may be repurposed as an open-drain communication signal. Internal control circuit 275 may assert a gate signal 276. Gate signal 276 may turn on pull-down device 270, and pull-down device 270 may pull down the voltage on bus 265. Pull-up resistor 215 may be chosen to be a resistor of a high resistance value so that pull-down device 270 may pull bus 265 to ground and consume a small amount of current. Bus 265 may be input to input 260 of primary device 250. Primary device 250 may respond to a low level on input 260.

In the example illustrated in FIG. 2, internal control circuit 275, gate signal 276 and pull-down device 270 may implement a system alert function, wherein an alert is asserted by asserted gate signal 276 thereby pulling bus 265 to ground, and wherein the alert is not asserted when the gate signal 276 is not asserted thereby allowing pull-up resistor 215 to pull bus 265 towards the power supply voltage. In one of various examples, secondary device 210 may be a high-power device which may be susceptible to high-temperature damage when subjected to conditions such as short-circuits or heavy loads. In the example illustrated in FIG. 2, secondary device 210 may include a temperature sensor. A temperature alert signal may be sent from secondary device 210 to primary device 250. Primary device 250 may respond by disabling secondary device 210 to prevent damage to secondary device 210. Primary device 250 may respond with other actions to prevent damage to secondary device 210.

Secondary device 210 may include very few external pins, and there may not be a pin available to implement a temperature alert signal. In the example illustrated in FIG. 2, bus 265 may implement a temperature alert signal. Internal control circuit 275 may receive an input from a temperature sensor (not shown) when the temperature of secondary device 210 exceeds a predetermined threshold. Gate signal 276 may be asserted, and pull-down device 270 may pull down bus 265. Primary device 250 may receive the low voltage signal at input 260 and interpret this as a temperature alert and respond accordingly.

This temperature alert example is intended for explanatory purposes and is not intended to limit the invention. In one of various examples, internal control circuit 275, gate signal 276 and pull-down device 270 may signal an overvoltage condition or an undervoltage condition. In one of various examples, internal control circuit 275, gate signal 276 and pull-down device 270 may signal that a data converter in secondary device 210 has completed a conversion and data is ready to be read by primary device 250. In one of various examples, internal control circuit 275, gate signal 276 and pull-down device 270 may signal that a timer in secondary device 210 has timed out. Internal control circuit 275, gate signal 276 and pull-down device 270 may communicate any condition on secondary device 210 over bus 265 as described previously.

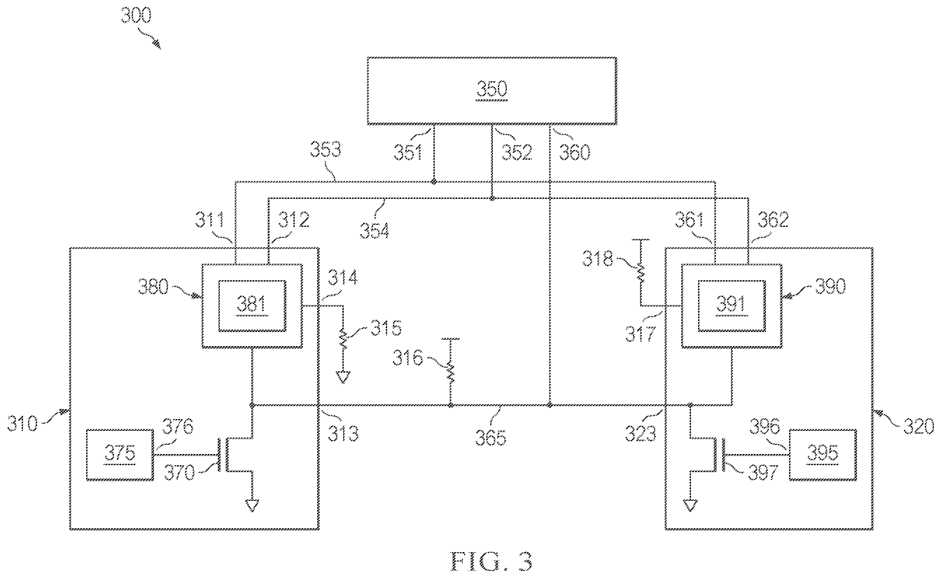

FIG. 3 illustrates an I2C system 300 including two secondary devices, the secondary devices 310, 320 with a respective multifunction address pin. A primary device 350 may include an output clock port 351. Primary device 350 may include a bidirectional data port 352. Primary device 350 may include input port 360.

Primary device 350 may be a microcontroller. Microcontrollers are systems on a chip that generally comprise a processor, a memory, a plurality of input/output ports, and a variety of peripheral devices. In particular, a variety of peripheral devices can be provided such as configurable logic cells, complementary waveform/output generators, dedicated arithmetic units, numerical controlled oscillators and programmable switch mode controllers. Microcontrollers may include host controllers to communicate with peripheral devices over a communication protocol, the communication protocol including but not limited to I2C. Primary device 350 may comprise a digital processor with memory and a plurality of programmable input and output ports. Primary device 350 may be a host device capable to communicate with multiple secondary devices over a shared bus protocol.

Secondary device 310 may comprise a peripheral device as described previously, including but not limited to a sensor, amplifier, oscillator, battery gauge, data converter or a logic device. Secondary device 310 may communicate with primary device 350 using a communication protocol, the communication protocol including but not limited to I2C.

Secondary device 320 may comprise a peripheral device as described previously, including but not limited to a sensor, amplifier, oscillator, battery gauge, data converter or a logic device. Secondary device 320 may communicate with primary device 350 using a communication protocol, the communication protocol including but not limited to I2C.

Output clock port 351 may be coupled to at least one secondary device via shared bus 353. Shared bus 353 may also be termed SCL or shared SCL bus. Bidirectional data port 352 may be coupled to at least one secondary device via shared bus 354. Shared bus 354 may also be termed SDA or shared SDA bus. In the example illustrated in FIG. 3, system 300 includes two secondary devices 310 and 320, but this is not intended to be limiting. Other examples may include a single secondary device or may include more than two secondary devices.

Secondary device 310 may include clock input port 311. Clock input port 311 may be coupled to shared SCL bus 353. Secondary device 310 may include bidirectional data port 312. Bidirectional data port 312 may be connected to shared SDA bus 354. Secondary device 310 may include first address port 313 and a second address port 314. As one of various examples, first address port 313 may be coupled to a power supply voltage through pull-up resistor 316 and second address port 314 may be coupled to a ground voltage through pull-down resistor 315.

Secondary device 320 may include clock input port 361. Clock input port 361 may be coupled to shared SCL bus 353. Secondary device 320 may include bidirectional data port 362. Bidirectional data port 362 may be coupled to shared SDA bus 354. Secondary device 320 may include first address port 323. First address port 323 may be coupled to a power supply voltage through pull-up resistor 316. Secondary device 320 may include second address port 317. Second address port 317 may be coupled to a power supply voltage through pull-up resistor 318.

In operation, in the example illustrated in FIG. 3, primary device 350 may transmit a clock signal on shared SCL bus 353 and may transmit a data signal on shared SDA bus 354. Secondary device 310 may receive the transmitted data signal on bidirectional data port 312. Secondary device 310 may receive the transmitted clock signal on clock input port 311. Secondary device 320 may receive the transmitted data signal on bidirectional data port 362. Secondary device 320 may receive the transmitted clock signal on clock input port 361.

Secondary device 310 may respond to transmissions with the decoded address field matching the chip address value. The chip address value may include a common address and a variable address. In the example illustrated in FIG. 3, the variable address of the chip address value of secondary device 310 may be set by the value stored in non-transitory memory location 381. In the example illustrated in FIG. 3, the variable address of the chip address value of secondary device 320 may be set by the value stored in non-transitory memory location 391. The variable chip address value may be the least significant bits of the chip address value, and the common chip address value may be the most significant bits of the chip address value.

At the first transmission from primary device 350, address decoder circuit 380 may sample the voltage at first address port 313. Address decoder circuit 380 may store the sampled values of first address port 313 in a non-transitory storage location 381, including but not limited to a volatile register or latch that stores the value of first address port 313 for as long as the device is receiving a supply voltage. In the example illustrated in FIG. 3, address decoder circuit 380 may store the value of first address port 313, storing a logic-high value into the non-transitory storage location 381.

At the first transmission from primary device 350, address decoder circuit 390 may sample the voltage at first address port 323. Address decoder circuit 390 may store the sampled value of first address port 323 in a non-transitory storage location 391, including but not limited to a volatile register or latch that stores the value of first address port 323 for as long as the device is receiving a supply voltage. In the example illustrated in FIG. 3, address decoder circuit 390 may store the value of first address port 323, storing a logic-high value into the non-transitory storage location 391.

The value stored in non-transitory storage location 381 may be accessed by address decoder circuit 380 as the variable portion of the chip address value of secondary device 310, address bit A0. Address decoder circuit 380 may compare the decoded address field to the chip address value for secondary device 310, with the least significant bits of the chip address value from the non-transitory storage location 381.

The value stored in non-transitory storage location 391 may be accessed by address decoder circuit 390 as the variable portion of the chip address value of secondary device 320, address bit A0. Address decoder circuit 390 may compare the decoded address field to the chip address value for secondary device 320, with the least significant bit of the chip address value from the non-transitory storage location 391.

In secondary device 310, address decoder circuit 380 may receive inputs from clock input port 311, bidirectional data port 312, first address port 313 and second address port 314. Address decoder circuit 380 may decode an address field based on clock input port 311 and bidirectional data port 312. In the example of FIG. 3, non-transitory storage location 381 may set the least-significant bit of the chip address value of secondary device 310. The voltage at second address port 314 may set the value of address bit A1, the next-to-least-significant bit of the chip address for secondary device 310.

In secondary device 320, address decoder circuit 390 may receive inputs from clock input port 361, bidirectional data port 362, first address port 323 and second address port 317. Address decoder circuit 390 may decode an address field based on signals received at clock input port 361 and bidirectional data port 362. In the example of FIG. 3, non-transitory storage location 391 may set the value of address bit A0, the least-significant bit of the chip address value of secondary device 320. The voltage at second address port 317 may set the value of address bit A1, the next-to-least-significant bit of the chip address value of secondary device 32.

In the example illustrated in FIG. 3, secondary device 310 and secondary device 320 may have different chip address values. In secondary device 310, address bit A1 may be set to logic low by pulldown resistor 315, and address bit A0 may be set to logic high by the value stored in non-transitory storage location 381. In secondary device 320, address bit A1 may be set to logic high by pullup resistor 318, and address bit A0 may be set to logic high by the value stored in non-transitory storage location 391. Secondary device 310 and secondary device 320 may be individually addressed by primary device 350 using address bit A0 and address bit A1.

In operation, address decoder circuit 380 in secondary device 310 may receive inputs from clock input port 311, bidirectional data port 312 and second address port 314 and compare the decoded address field to the chip address value for secondary device 310, the chip address value for secondary device 310 including the common address and the variable address, the variable address including address bit A0 set by non-transitory storage location 381 and address bit A1 set by second address port 314. As SCL bus 353 and SDA bus 354 are shared by secondary device 310 and secondary device 320, address decoder circuit 390 in secondary device 320 may receive inputs at clock input port 361, bidirectional data port 362, first address port 323 and second address port 317 and may compare the decoded address field to the chip address value for secondary device 320, the chip address value for secondary device 320 including the common address and the variable address, the variable address including the address bit A0 set by non-transitory storage location 391 and the address bit A1 set by second address port 317.

At the first transmission from primary device 350, address decoder circuit 380 in secondary device 310 may store the value of first address port 313 into non-transitory storage location 381. In the example illustrated in FIG. 3, address decoder circuit 380 may store the value of first address port 313, storing a logic-high value for address bit A0 into a non-transitory storage location 381. At the first transmission from primary device 350, address decoder circuit 390 in secondary device 320 may store the value of first address port 323 into a non-transitory storage location 391. In the example illustrated in FIG. 3, address decoder circuit 390 may store the value of first address port 323, storing a logic-high value for address bit A0 into a non-transitory storage location 391. The first transmission from primary device 350 may be initiated based on a first change in the level of SCL bus 353 or SDA bus 354.

Address decoder circuit 380 in secondary device 310 may compare the decoded address field to the chip address value for secondary device 310, using the value of address bit A0 from the non-transitory storage location 381, and using the value of address bit A1 from second address port 314. Address decoder circuit 390 in secondary device 320 may compare the decoded address field to the chip address value for secondary device 320, using the value of address bit A0 from the non-transitory storage location 391 and using the value of address bit A1 from second address port 317.

Once the value of address bit A0 is stored in non-transitory storage location 381 in secondary device 310, first address port 313 in secondary device 310 may be repurposed for a new function. In the example illustrated in FIG. 3, internal control circuit 375 may assert a gate signal 376. Gate signal 376 may turn on pull-down device 370, and pull-down device 370 may pull down the voltage on bus 365. Pull-up resistor 316 may be chosen to be a resistor of a high resistance value so that pull-down device 370 may pull bus 365 to ground. Bus 365 may be coupled to input 360 of primary device 350.

Once the value of address bit A0 has been stored in non-transitory storage location 391 in secondary device 320, first address port 323 in secondary device 320 may be repurposed for a new function. In the example illustrated in FIG. 3, internal control circuit 395 may assert a gate signal 396. Gate signal 396 may turn on pull-down device 397, and pull-down device 397 may pull down the voltage on bus 365. As indicated above, pull-up resistor 316 may be chosen to be a resistor of a high resistance value so that pull-down device 397 may pull bus 365 to ground. Bus 365 may be input to input 360 of primary device 350.

In the example illustrated in FIG. 3, internal control circuit 375, gate signal 376 and pull-down device 370 may implement an open-drain communication signal from secondary device 310 to primary device 350. In other examples, secondary device 310 may communicate with other devices (not shown) coupled to bus 365. Internal control circuit 395, gate signal 396 and pull-down device 397 may implement an open-drain communication signal from secondary device 320 to primary device 350. As the logic-high level on bus 365 is set by pull-up resistor 316, multiple secondary devices with internal pull-down devices may share bus 365 and respectively communicate with primary device 350.

In one of various examples, secondary device 310 may be a high-power device which may be susceptible to high-temperature damage when subjected to conditions such as short-circuits or heavy loads. In this example, secondary device 310 may include a temperature sensor. A temperature alert signal may be sent from secondary device 310 to primary device 350. Primary device 350 may respond by disabling secondary device 310 to prevent damage to secondary device 310.

Secondary device 310 may include very few external pins, and there may not be a pin available to implement a temperature alert signal. In the example illustrated in FIG. 3, bus 365 may enable transmission of a temperature alert signal. Internal control circuit 375 may receive an input from a temperature sensor (not shown) when the temperature of secondary device 310 exceeds a predetermined threshold. Gate signal 376 may be asserted, and pull-down device 370 may pull down bus 365. Primary device 350 may receive the low voltage signal at input 360 and interpret this as a temperature alert and respond accordingly.

In one of various examples, secondary device 320 may be a high-power device which may be susceptible to high-temperature damage when subjected to conditions such as short-circuits or heavy loads. In this example, secondary device 320 may include a temperature sensor. A temperature alert signal may be sent from secondary device 320 to primary device 350. Primary device 350 may respond by disabling secondary device 320 to prevent damage to secondary device 320.

Secondary device 320 may include very few external pins, and there may not be a pin available to implement a temperature alert signal. In the example illustrated in FIG. 3, bus 365 may enable transmission of a temperature alert signal. Internal control circuit 395 may receive an input from a temperature sensor (not shown) when the temperature of secondary device 320 exceeds a predetermined threshold. Gate signal 396 may be asserted, and pull-down device 397 may pull down bus 365. Primary device 350 may receive the low voltage signal at input 360 and interpret this as a temperature alert and respond accordingly.

In the example illustrated in FIG. 3, both secondary device 310 and secondary device 320 may pull down bus 365 and send a system alert signal to primary device 350. Primary device 350 may send further transactions on SCL bus 353 and SCL bus 354 to determine which device issued the system alert, and to determine the exact type of condition which caused the system alert.

This temperature alert example is intended for explanatory purposes and is not intended to limit the invention. Any other signal may be communicated over bus 365, including but not limited to system alert signals.

In one of various examples, internal control circuit 375, gate signal 376 and pull-down device 370 may signal an overvoltage or undervoltage condition. In one of various examples, internal control circuit 375, gate signal 376 and pull-down device 370 may signal that a data converter in secondary device 310 has completed a conversion. In one of various examples, internal control circuit 375, gate signal 376 and pull-down device 370 may signal that a timer in secondary device 310 has timed out.

In one of various examples, internal control circuit 395, gate signal 396 and pull-down device 397 may signal that a data converter in secondary device 320 has completed a conversion. In one of various examples, internal control circuit 395, gate signal 396 and pull-down device 397 may signal that a timer in secondary device 320 has timed out.

The specific examples illustrated in FIG. 3 are intended for explanatory purposes and is not intended to limit the invention. Any other signal may be communicated over bus 365, including but not limited to system alert signals.

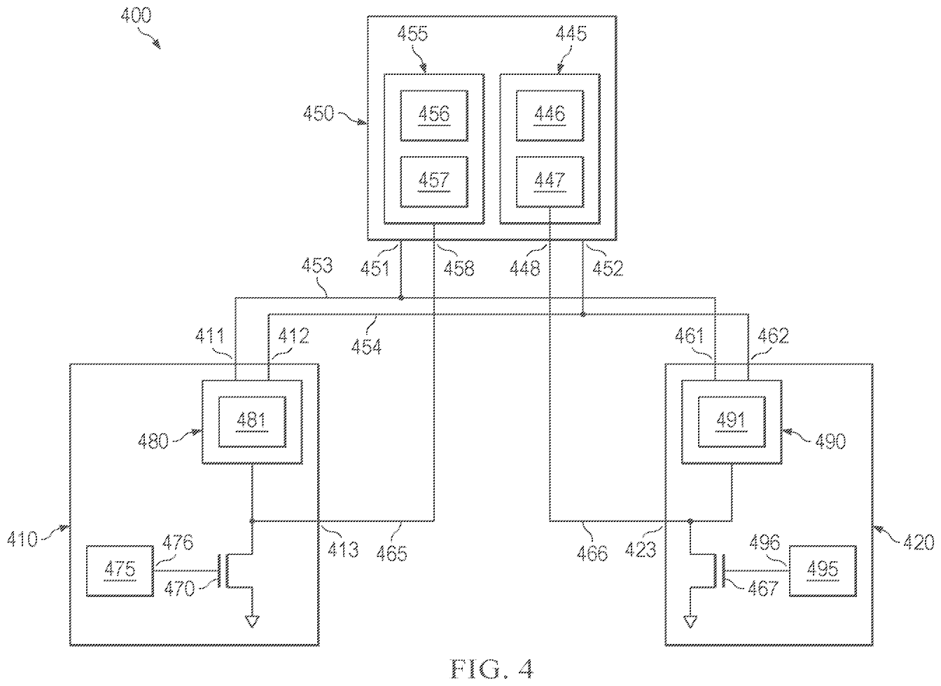

FIG. 4 illustrates an I2C system 400 including two secondary devices, with a respective multifunction address pin. The example illustrated in FIG. 4 does not require external resistors to independently address secondary devices 410 and 420.

A primary device 450 may include an output clock port 451. Primary device 450 may include a bidirectional data port 452. Primary device 450 may include first bidirectional port 458 and second bidirectional port 448.

Primary device 450 may be a microcontroller. Microcontrollers are systems on a chip that generally comprise a processor, a memory, a plurality of input/output ports, and a variety of peripheral devices. In particular, a variety of peripheral devices can be provided such as configurable logic cells, complementary waveform/output generators, dedicated arithmetic units, numerical controlled oscillators and programmable switch mode controllers. Microcontrollers may include host controllers to communicate with peripheral devices over a communication protocol, the communication protocol including but not limited to I2C. Primary device 450 may comprise a digital processor with memory and a plurality of programmable input and output ports. Primary device 450 may be a host device capable to communicate with multiple secondary devices over a shared bus protocol.

Secondary device 410 may comprise a peripheral device as described previously, including but not limited to a sensor, amplifier, oscillator, battery gauge, data converter or a logic device. Secondary device 410 may communicate with primary device 450 using a communication protocol, the communication protocol including but not limited to I2C.

Secondary device 420 may comprise a peripheral device as described previously, including but not limited to a sensor, amplifier, oscillator, battery gauge, data converter or a logic device. Secondary device 420 may communicate with primary device 450 using a communication protocol, the communication protocol including but not limited to I2C.

Primary device 450 may include a first bidirectional port circuit 455 coupled to first bidirectional port 458. First bidirectional port 458 may be a general-purpose input output (GPIO) port. First bidirectional port circuit 455 may include first output stage 456 which may comprise circuitry to drive first bidirectional port 458. First bidirectional port circuit 455 may include first input stage 457 which may include a comparator or receiver or other circuit for detecting an input voltage on bus 465.

Primary device 450 may include a second bidirectional port circuit 445 coupled to second bidirectional port 448. Second bidirectional port 448 may be a general-purpose input output (GPIO) port. Second bidirectional port circuit 445 may include second output stage 446 which may include circuitry to drive second bidirectional port 448. Second bidirectional port circuit 445 may include second input stage 447 which may include a comparator or receiver or other circuit for detecting an input voltage on bus 466.

Output clock port 451 may be coupled to at least one secondary device via shared bus 453. Shared bus 453 may also be termed SCL or shared SCL bus. Bidirectional data port 452 may be coupled to at least one secondary device via shared bus 454. Shared bus 454 may also be termed SDA or shared SDA bus. In the example illustrated in FIG. 4, system 400 includes two secondary devices 410 and 420, but this is not intended to be limiting. Other examples may include a single secondary device or may include more than two secondary devices.

Secondary device 410 may include clock input port 411. Clock input port 411 may be coupled to shared SCL bus 453. Secondary device 410 may include bidirectional data port 412. Bidirectional data port 412 may be coupled to shared SDA bus 454. Secondary device 410 may include a first address port 413 coupled to bus 465. Bus 465 may be driven by first output stage 456 of first bidirectional port circuit 455 of primary device 450.

Secondary device 420 may include clock input port 461. Clock input port 461 may be coupled to shared SCL bus 453. Secondary device 420 may include bidirectional data port 462. Bidirectional data port 462 may be coupled to shared SDA bus 454. Secondary device 420 may include first address port 423 coupled to bus 466. Bus 466 may be driven by second output stage 446 of second bidirectional port circuit 445 of primary device 450.

In operation, in the example illustrated in FIG. 4, primary device 450 may transmit a clock signal on shared SCL bus 453 and may transmit a data signal on shared SDA bus 454. Secondary device 410 may receive the transmitted data signal on bidirectional data port 412. Secondary device 410 may receive the transmitted clock signal on clock input port 411. Secondary device 420 may receive the transmitted data signal on bidirectional data port 462. Secondary device 420 may receive the transmitted clock signal on clock input port 461. Initially, first output stage 456 of first bidirectional port circuit 455 may be enabled, and first input stage 457 of first bidirectional port circuit 455 may be disabled, configuring first bidirectional port 458 as an output. Initially, first output stage 446 of first bidirectional port circuit 445 may be enabled, and first input stage 447 of first bidirectional port circuit 455 may be disabled, configuring first bidirectional port 448 as an output.

Address decoder circuit 480 may receive inputs from clock input port 411, bidirectional data port 412, and first address port 413. Address decoder circuit 480 may decode an address field based on signals received at clock input port 411 and bidirectional data port 412. In the example of FIG. 4, non-transitory storage location 381 may set the value of address bit A0, the least-significant bit of the chip address value of secondary device 410 based on the voltage value at first address port 413.

Address decoder circuit 490 may receive inputs from clock input port 461, bidirectional data port 462, and first address port 423. Address decoder circuit 490 may decode an address field based on signals received at clock input port 461 and bidirectional data port 462. In the example of FIG. 4, non-transitory storage location 391 may set the value of address bit A0, the least-significant bit of the chip address value of secondary device 420 based on the voltage value at first address port 423.

In operation, address decoder circuit 480 in secondary device 410 may receive inputs from clock input port 411, bidirectional data port 412, and may compare the decoded address field to the chip address value for secondary device 410. As SCL bus 453 and SDA bus 454 are shared by secondary device 410 and secondary device 420, address decoder circuit 490 in secondary device 420 may receive input at clock input port 461, bidirectional data port 462, first address port 423 and may compare the decoded address field to the chip address value for secondary device 420.

At the first transmission from primary device 450, address decoder circuit 480 in secondary device 410 may store the value of address port 413 into a non-transitory storage location 481. In the example illustrated in FIG. 4, address decoder circuit 480 may store the value of address bit A0 responsive to the voltage appearing at address port 413 into a non-transitory storage location 481. Address decoder circuit 490 in secondary device 420 may store the value of address bit A0 responsive to the voltage appearing at address port 423 into a non-transitory storage location 491. The first transmission from primary device 450 may be initiated based on a first change in the level of SCL bus 453 or SDA bus 454. The first transmission from primary device 450 may be initiated based on a predetermined sequence of levels on SCL bus 453 and SDA bus 454.

Address decoder circuit 480 in secondary device 410 may compare the decoded address field to the chip address value of secondary device 410, the chip address value including the value of address bit A0 from the non-transitory storage location 481. Address decoder circuit 490 in secondary device 420 may compare the decoded address field to the chip address value of secondary device 420, the chip address value including the value of address bit A0 from the non-transitory storage location 491.

Once the value of address bit A0 has been stored in non-transitory storage location 481 in secondary device 410, first output stage 456 of first bidirectional port circuit 455 may be disabled, and first input stage 457 of first bidirectional port circuit 455 may be enabled. First input stage 457 of first bidirectional port circuit 455 may be enabled with a weak pull-up device to hold a logic-high level on bus 465 when there is no other device driving bus 465. Once the value of address bit A0 is stored in non-transitory storage location 481 in secondary device 410 and first output stage 456 has been disabled, first address port 413 in secondary device 410 may be repurposed for a new function. Once the value of address bit A0 is stored in a non-transitory storage location 491 in secondary device 420 and second output stage 446 has been disabled, first address port 423 in secondary device 420 may be repurposed for a new function.

Once the value of address bit A0 has been stored in non-transitory storage location 491 in secondary device 420, first output stage 446 of first bidirectional port circuit 445 may be disabled, and first input stage 447 of first bidirectional port circuit 445 may be enabled. First input stage 447 of first bidirectional port circuit 445 may be enabled with a weak pull-up device to hold a logic-high level on bus 466 when there is no other device driving bus 466. Once the value of address bit A0 is stored in non-transitory storage location 491 in secondary device 420 and first output stage 446 has been disabled, first address port 423 in secondary device 420 may be repurposed for a new function.

In the example illustrated in FIG. 4, internal control circuit 475, gate signal 476 and pull-down device 470 may communicate with primary device 450 over bus 465. In the example illustrated in FIG. 4, internal control circuit 495, gate signal 496 and pull-down device 467 may communicate with primary device 450 over bus 466.

In the example illustrated in FIG. 4, internal control circuit 475 may assert a gate signal 476. Gate signal 476 may turn on pull-down device 470, and pull-down device 470 may pull down the voltage on bus 465. The pull-up device in input stage 457 in bidirectional port circuit 455 may be chosen to be a resistor of a high resistance value so that pull-down device 470 may pull bus 465 to ground. Bus 465 may be received by input stage 457 of bidirectional port 455 of primary device 450. In this manner, a communication signal may be sent from secondary device 410 to primary device 450.

In the example illustrated in FIG. 4, internal control circuit 495 may assert a gate signal 496. Gate signal 496 may turn on pull-down device 467, and pull-down device 467 may pull down the voltage on bus 466. A pull-up device in second input stage 447 in second bidirectional port circuit 445 may be chosen to be a resistor of a high resistance value so that pull-down device 467 may pull bus 466 to ground. Bus 466 may be received by second input stage 447 of second bidirectional port circuit 445 of primary device 450. In this manner, a communication signal may be sent from secondary device 420 to primary device 450. Bus 465 and bus 466 may be respectively replaced with a direct wire connection without exceeding the scope.

In one of various examples, secondary device 410 may be a high-power device which may be susceptible to high-temperature damage when subjected to conditions such as short-circuits or heavy loads. In this example, secondary device 410 may include a temperature sensor. A temperature alert signal may be sent from secondary device 410 to primary device 450. Primary device 450 may respond by disabling secondary device 410 to prevent damage to secondary device 410.

Secondary device 410 may include few external pins, and there may not be a pin available to implement a temperature alert signal. In the example illustrated in FIG. 4, bus 465 may enable transmission of a temperature alert signal. Internal control circuit 475 may receive an input from a temperature sensor (not shown) when the temperature of secondary device 410 exceeds a predetermined threshold. Gate signal 476 may be asserted, and pull-down device 470 may pull down bus 465. Primary device 450 may receive the low voltage signal at first input stage 457 of first bidirectional port circuit 455 and interpret this as a temperature alert and respond accordingly.

In one of various examples, secondary device 420 may be a high-power device which may be susceptible to high-temperature damage when subjected to conditions such as short-circuits or heavy loads. In this example, secondary device 420 may include a temperature sensor. A temperature alert signal may be sent from secondary device 420 to primary device 450. Primary device 450 may respond by disabling secondary device 420 to prevent damage to secondary device 420.

Secondary device 420 may include few external pins, and there may not be a pin available to implement a temperature alert signal. In the example illustrated in FIG. 4, bus 466 may enable transmission of a temperature alert signal. Internal control circuit 495 may receive an input from a temperature sensor (not shown) when the temperature of secondary device 420 exceeds a predetermined threshold. Gate signal 496 may be asserted, and pull-down device 467 may pull down bus 466. Primary device 450 may receive the low voltage signal at second input stage 447 of second bidirectional input circuit 445 and interpret this as a temperature alert and respond accordingly.

This temperature alert example is intended for explanatory purposes and is not intended to limit the invention. Any other signal may be communicated over bus 465, including but not limited to system alert signals. Any other signal may be communicated over bus 466, including but not limited to system alert signals.

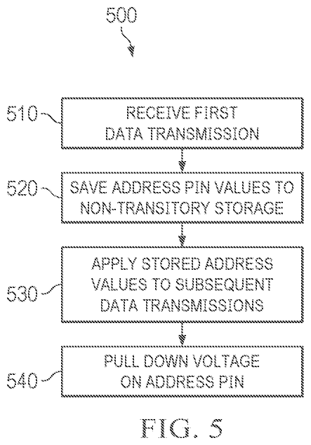

FIG. 5 illustrates a method of configuring and using a multifunction address pin.

At operation 510, a secondary device may receive a first data transmission.

At operation 520, the secondary device may store the values on one or more address pins to a non-transitory storage medium. Stored values may reflect the logic level on the one or more address pins.

At operation 530, the secondary device may apply the stored address values to the chip address value of the secondary device. The chip address value may be compared with the decoded address field received from the primary device on subsequent data transmissions.

At operation 540, the secondary device may pull down the voltage on one or more address pins to signal the primary device or any other device coupled to the one or more address pins. The secondary device may signal a system alert, failure event or other event to the primary device.

1. A device comprising:
a clock input port;
a bidirectional data port;
an address port;
an address decoder circuit coupled to the clock input port, the bidirectional data port and the address port, the address decoder circuit to receive a clock signal from the clock input port and to receive a data signal from the bidirectional data port, and to decode the clock signal and the data signal to generate a decoded address field and the address decoder circuit to store the value of the address port in a non-transitory storage location and to compare at least one bit of the decoded address field to the stored value of the address port, and
an internal control circuit to output a control signal to a pull-down circuit based on a predetermined condition, the pull-down circuit to selectively couple the address port to a ground node based on the value of the control signal.

2. The device as claimed in claim 1, the pull-down circuit comprising a metal-oxide semiconductor (MOS) device with a gate node coupled to the control signal, a source node coupled to the ground connection and the drain node coupled to the address port.

3. The device as claimed in claim 1, the clock signal comprising an I2C SCL clock signal.

4. The device as claimed in claim 1, the data signal comprising an I2C SDA data signal.

5. The device as claimed in claim 1, the predetermined condition comprising a system alert.

6. The device as claimed in claim 1, the predetermined condition comprising a thermal limit.

7. A system comprising:
a primary device to drive a clock bus and a data bus and to couple to a control bus;
a plurality of secondary devices comprising:
a clock input port to couple to the clock bus;
a bidirectional data port to couple to the data bus;
an address port to couple to the control bus;
an address decoder circuit coupled to the clock input port, the bidirectional data port and the address port, the address decoder circuit to receive a clock signal from the clock input port and to receive a data signal from the bidirectional data port, and to decode the clock signal and the data signal to generate a decoded address field and the address decoder circuit to store the value of the address port in a non-transitory storage location and to compare at least one bit of the decoded address field to the stored value of the address port, and
an internal control circuit to output a control signal to a pull-down circuit based on a predetermined condition, the pull-down circuit to selectively couple the address port to a ground node based on the value of the control signal.

8. The system as claimed in claim 7, the pull-down circuit comprising a metal-oxide semiconductor (MOS) device with a gate node coupled to the control signal, a source node coupled to the ground connection and the drain node coupled to the address port.

9. The system as claimed in claim 7, the clock signal comprising an I2C SCL clock signal.

10. The system as claimed in claim 7, the data signal comprising an I2C SDA data signal.

11. The system as claimed in claim 7, the predetermined condition comprising a system alert.

12. The system as claimed in claim 7, the predetermined condition comprising a thermal limit.

13. A method comprising:
receiving a data transmission from a primary device at a secondary device,
storing the value of an address port to a stored address location in a non-transitory storage device,
decoding the data transmission to generate a decoded address field,
comparing at least one bit of the decoded address field with the stored address port value, and
pulling down the voltage of the address port, based on a predetermined condition of the secondary device, to signal a status condition to the primary device.

14. The method as claimed in claim 13, the predetermined condition comprising a system alert.

15. The method as claimed in claim 13, the predetermined condition comprising a thermal limit.

16. The method as claimed in claim 13, the data transmission comprising an I2C write transmission.

17. The method as claimed in claim 13, the data transmission comprising an I2C read transmission.
